(19) United States
(12) Patent Application Publication
(10) Pub. No.: US 2012/0293857 A1
(43) Pub. Date: Nov. 22, 2012

(54) Electrophoretic Display Apparatus and Method for Manufacturing the Same

(76) Inventors: OhNam KWON, Paju-si (KR); SeungHan Paek, Bucheon-si (KR); ChoonHo Park, Paju-si (KR); YoungHoon Noh, Paju-si (KR); YoungMu Oh, Seoul (KR); Sang-Il Shin, Paju-si (KR); Goeun Jung, Paju-si (KR); Youngjun Yu, Seoul (KR); Jeongwon Lee, Paju-si (KR)

(21) Appl. No.: 13/339,796

(22) Filed: Dec. 29, 2011

(30) Foreign Application Priority Data
May 20, 2011 (KR) 10-2011-0047749
May 26, 2011 (KR) 10-2011-0049899

(51) Int. Cl. G02F 1/167; B32B 37/02; B32B 37/14; G03F 7/20

(52) U.S. Cl. 359/296; 430/319; 156/146

(57) ABSTRACT

Disclosed are an electrophoretic display device and a manufacturing method thereof, which can enhance display quality and manufacturing efficiency. The electrophoretic display device includes a plurality of partition walls, sealing materials, a display solvent, and a second substrate. The partition walls are formed at a first substrate, and respectively define a plurality of unit pixel regions. The sealing materials are formed on the partition walls. The display solvent includes a plurality of charged particles and a solvent, and is filled into the unit pixel regions. The second substrate is adhered to the sealing materials to seal the unit pixel regions.

### CROSS-REFERENCE TO RELATED APPLICATIONS

This application claims the benefit of the Korean Patent Application No. 10-2011-0047749 filed on May 20, 2011, and Korean Patent Application No. 10-2011-0049899 filed on May 26, 2011, which is hereby incorporated by reference as if fully set forth herein.

### BACKGROUND

1. Field of the Invention

The present invention relates to a display device, and more particularly, an electrophoretic display device and a manufacturing method thereof, which can enhance display quality and manufacturing efficiency.

2. Discussion of the Related Art

Electrophoretic display devices denote devices that display an image with electrophoresis in which colored charged particles move by an electric field given from the outside. Herein, electrophoresis denotes an electrophoretic motion where with charged particles being dispersed into a solvent, the charged particles moves inside the solvent by Coulomb force when applying an electric field.

Electrophoretic display devices using electrophoresis have bistability, and thus can maintain a displayed image for a long time even when an applied voltage is removed. That is, since electrophoretic display devices maintain a constant screen for a long time even when a voltage is not continuously applied thereto, the electrophoretic display devices are display devices suitable for an e-book field that does not require the quick change of a screen.

Also, electrophoretic display devices are not dependent on a viewing angle unlike Liquid Crystal Display (LCD) devices, and moreover, provide an image comfortable for eyes by the degree similar to papers because reflecting external light to display an image. Furthermore, electrophoretic display devices have flexibility, low power consumption, and eco like. Accordingly, the demand of electrophoretic display devices is increasing.

FIG. 1 is a view illustrating a related art electrophoretic display device.

Referring to FIG. 1, the related art electrophoretic display device includes a lower substrate 10 and an upper substrate 20 that are facing-coupled to each other, and an electrophoretic film 30 disposed between the lower substrate 10 and the upper substrate 20.

The lower substrate 10 includes a plurality of gate lines and data lines (not shown) that are formed to intersect each other. A plurality of unit pixels are defined by the intersection of the gate lines and data lines.

A Thin Film Transistor (TFT) 12 and a pixel electrode 14 are formed in each of the unit pixels formed at the lower substrate 10.

The thin film transistor 12 is switched according to a scan signal that is applied thereto through a gate line. By switching of the thin film transistor 12, a data voltage supplied to a data line is applied to the pixel electrode 14.

The upper substrate 20 includes a common electrode 22 facing the pixel electrode.

The electrophoretic film 30 includes a plurality of charged particles 34, a plurality of microcapsules 32 formed of a solvent, an adhesive layer coated on the microcapsules 32, and a passivation layer for protecting the adhesive layer.

Herein, some of the charged particles 34 are electrically charged to a positive (+) polarity, and the other of the charged particles 34 are electrically charged to a negative (−) polarity.

When an electric field is generated between the pixel electrode 14 of the lower substrate 10 and the common electrode 22 of the pixel electrode 14, the charged particles 34 included in the microcapsules 32 move to the upper substrate 20 or the lower substrate 10 by electrophoresis, and thus realize an image.

The lower substrate 10 that is formed through a separate process, the upper substrate 20 that is formed by a separate process different from the formation process of the lower substrate 10, and the electrophoretic film 30 that is adhered to the upper substrate 20 by a lamination process are manufactured separately, and then by attaching the two substrates 10 and 20, the related art electrophoretic display device is completed.

Herein, the electrophoretic film 30 is managed and conveyed, with the electrophoretic film 30 being adhered to the upper substrate 20. Afterward, the passivation layer adhered to the adhesive layer is removed from the upper substrate 20 with the electrophoretic film 30 adhered thereto so as to expose the adhesive layer, and the upper substrate 20 and the lower substrate 10 are coupled to each other by exposing the adhesive layer, thereby completing the electrophoretic display device.

In the related art electrophoretic display device, since the lower substrate 10, upper substrate 20, and electrophorectic film 30 are manufactured separately, a manufacturing process is complicated, and much time is taken in manufacturing, causing the decrease in manufacturing efficiency. Also, it is difficult to accurately arrange the upper substrate 20 and the lower substrate 10, and a failure occurs.

### SUMMARY

Accordingly, the present invention is directed to provide an electrophoretic display device and a manufacturing method thereof that substantially obviate one or more problems due to limitations and disadvantages of the related art.

An aspect of the present invention is directed to provide an electrophoretic display device with enhanced display quality and a manufacturing method thereof.

Another aspect of the present invention is directed to provide an electrophoretic display device and a manufacturing method thereof which can enhance the manufacturing efficiency of the electrophoretic display device.

Another aspect of the present invention is directed to provide a new type electrophoretic display device in which an electrophoretic layer is directly formed at a lower substrate, and to a manufacturing method which couples an upper substrate to the lower substrate with the electrophoretic layer directly formed therein.

Another aspect of the present invention is directed to provide an electrophoretic display device which can realize a high-quality image in various colors, and a manufacturing method thereof.

In addition to the aforesaid objects of the present invention, other features and advantages of the present invention will be described below, but will be clearly understood by those skilled in the art from descriptions below. In addition to the aforesaid features and effects of the present invention, other features and effects of the present invention can be newly construed from the embodiments of the present invention.

Additional advantages and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these and other advantages and in accordance with the purpose of the invention, as embodied and broadly described herein, there is provided an electrophoretic display device including: a plurality of partition walls formed at a first substrate, and defining a plurality of unit pixel regions; sealing materials formed on the partition walls; a display solvent including a plurality of charged particles and a solvent, and filled into the unit pixel regions; and a second substrate adhered to the sealing materials to seal the unit pixel regions.

In another aspect of the present invention, there is provided a manufacturing method of an electrophoretic display device including: forming a plurality of partition walls which define a plurality of unit pixel regions, at a first substrate; forming sealing materials on the partition walls; filling a display solvent into the unit pixel regions, the display solvent including a plurality of charged particles and a solvent; and attaching the first substrate to a second substrate corresponding to the first substrate.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 is a view illustrating a related art electrophoretic display device;

FIG. 2 is a view illustrating an electrophoretic display device according to a first embodiment of the present invention;

FIGS. 3 and 4 are views illustrating an array substrate of the electrophoretic display device according to the first embodiment of the present invention;

FIGS. 5 to 10 are views illustrating the essentials of a manufacturing method of an electrophoretic display device according to a first embodiment of the present invention;

FIG. 11 is a view illustrating an electrophoretic display device according to a second embodiment of the present invention; and

FIGS. 12 to 14 are views illustrating a manufacturing method of an electrophoretic display device according to a second embodiment of the present invention.

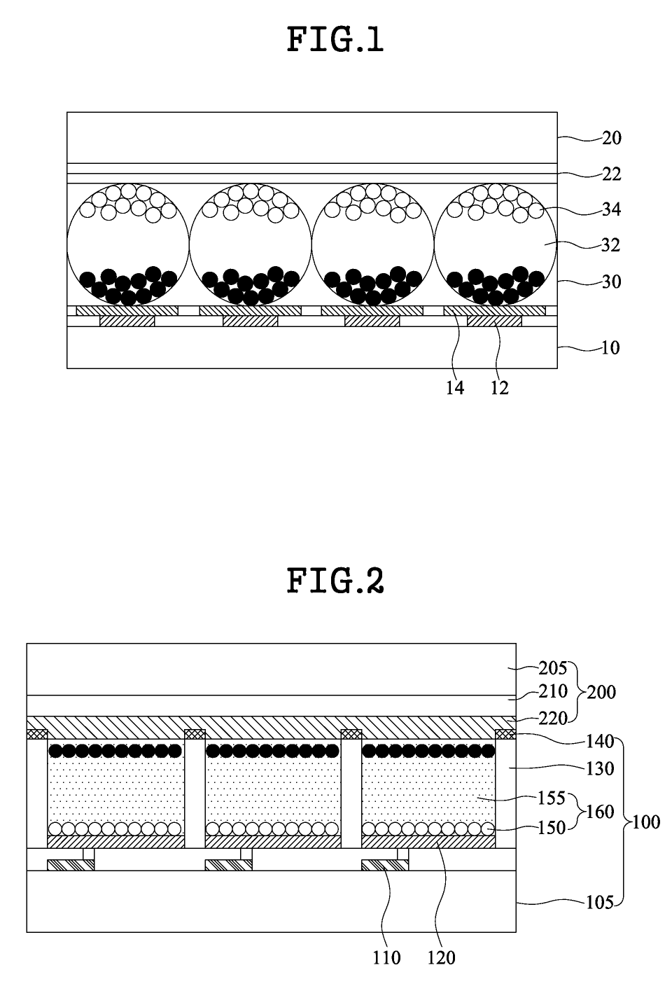

### DETAILED DESCRIPTION OF THE INVENTION

Reference will now be made in detail to the exemplary embodiments of the present invention, examples of which are illustrated in the accompanying drawings. Wherever possible, the same reference numbers will be used throughout the drawings to refer to the same or like parts.

Hereinafter, an electrophoretic display device and a manufacturing method thereof according to embodiments of the present invention will be described in detail with reference to the accompanying drawings.

In description of embodiments of the present invention, when a structure is described as being formed at an upper portion/lower portion of another structure or on/under the other structure, this description should be construed as including a case where the structures contact each other and moreover a case where a third structure is disposed therebetween.

The present invention proposes an electrophoretic display device where a display solvent with charged particles and a solvent is internalized in an array substrate, and a manufacturing method thereof. In the embodiment, the electrophoretic display device is completed, and then the array substrate is disposed a lower portion of the electrophoretic display device. Accordingly, the array substrate may be referred to as a lower substrate. Also, an upper substrate that is coupled to the array substrate to seal a unit display region is provided.

The technical spirit and scope of the present invention to be described below may be applied to an electrophoretic display device in which charged particles internalized in a lower substrate are colored in black and white, and thus which displays a mono image.

Moreover, the technical spirit and scope of the present invention may be applied to an electrophoretic display device in which charged particles internalized in a lower substrate are colored in black and white and a plurality of color filters are formed at an upper substrate, and thus which displays a color image.

Moreover, the technical spirit and scope of the present invention may be applied even to an electrophoretic display device in which charged particles are colored in red, blue, green, yellow, cyan, magenta, black, and white, and thus which realizes a color image.

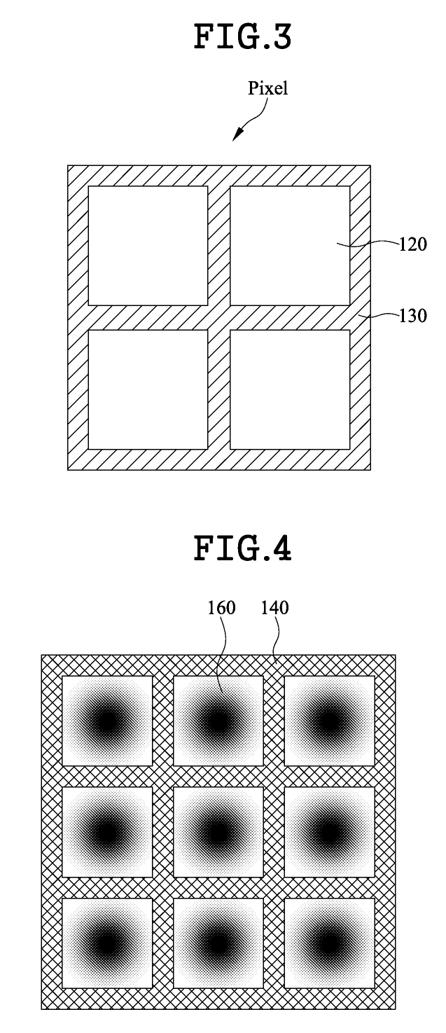

FIG. 2 is a view illustrating an electrophoretic display device according to a first embodiment of the present invention. FIGS. 3 and 4 are views illustrating an array substrate of the electrophoretic display device according to the first embodiment of the present invention.

Referring to FIGS. 2 to 4, the electrophoretic display device according to the first embodiment of the present invention includes a lower substrate 100 with a display solvent 160 internalized in the array substrate and an upper substrate 200.

The lower substrate 100 uses a transparent first substrate 105, formed of a glass or plastic such as PET, as a base substrate. When the first substrate 105 is formed of plastic, the first substrate 105 has flexibility. By using the first substrate 105 having flexibility, it is easy to treat the electrophoretic display device in manufacturing and after completion, and durability can be enhanced. However, the first substrate 105 is not limited to a transparent material. The first substrate 105 may use a metal substrate such as a thin stainless steel. When a thin metal substrate is used as the first substrate 105, by enhancing flexibility, the durability of the electrophoretic display device can be enhanced.

Although not shown, an inorganic layer such as silicon nitride or silicon oxide is thinly deposited on the first substrate 105. The inorganic layer prevents moisture from penetrating into the array substrate.

Although not shown, the first substrate 105 includes a plurality of gate lines and data lines that are formed to intersect.

A plurality of unit pixels are defined by the intersection of the gate lines and data lines. A thin film transistor 110 being a switching element and a pixel electrode 120, where a current is controlled through the thin film transistor 110, are formed in each of the unit pixels.

Each of the gate lines and data lines may be formed as a single layer that is formed of silver (Ag), aluminum (Al), or an alloy thereof which has low resistivity. Also, each gate line and data line may be formed as a multi layer further including a layer that is formed of chromium (Cr), titanium (Ti), tantalum (Ta), molybdenum (Mo), or MoTi which is has excellent electric characteristic.

The thin film transistor 110 has a gate electrode connected to a gate line, a source electrode connected to a data line, and a drain electrode connected to the pixel electrode 120.

The pixel electrode 120 is formed in each unit pixel. The pixel electrode 120 is formed as a conductive metal layer, in which case the pixel electrode 120 may be formed as a transparent metal layer or an opaque metal layer. Since external light is reflected and is discerned by a user, the electrophoretic display device of the present invention may use an opaque metal thin layer having excellent reflectivity as the pixel electrode 120.

The pixel electrode 120 may be formed of copper (Cu), Al, or indium tin oxide (ITO). Furthermore, the pixel electrode 120 may be formed by stacking nickel (Ni) and/or gold (Au) on Cu, Al, or ITO.

A data voltage is applied to the pixel electrode 120 by switching of the thin film transistor 110.

Each of the partition walls 130 that defines a unit pixel region is formed at the lower substrate 100. Each of the partition walls 130, as illustrated in FIG. 3, is formed in a lattice type at the lower substrate 100, and defines the unit pixel region such that one lattice room becomes one unit pixel. The pixel electrode 120 is formed in each unit pixel region defined by each of the partition walls 130. As a result, each of the partition walls 130 surrounds the pixel electrode 120 that is formed in the unit pixel region. A certain space is formed in each unit pixel by each of the partition walls 130, and the display solvent 160 is internalized in the space.

Herein, the display solvent 160 is formed of a plurality of charged particles 150 and a solvent that acts as a medium enabling moving of the charged particles 150.

An interlayer (not shown) may be further formed in the unit pixel region defined by each of the partition walls 130, for preventing an interaction between the display solvent 160 and each of the partition walls 130. The interlayer blocks electric gravitation between each of the partition walls 130 and the charged particles 150, and thus, the charged particles 150 can be controlled only by a voltage applied to the pixel electrode 120 and a voltage applied to a common electrode that is formed at the upper substrate 200.

Each of the partition walls 130 is formed to have a certain height (for example, a height of about 10 um to about 100 um) and width (for example, a width of about 5 um to about 30 um).

The partition walls 130 may be formed by a photolithography process or a mold printing process.

The partition walls 130 may be formed of an uncharged material such that the charged particles 150 are not coupled to each other by the electric force of the partition walls 130. In an embodiment of the present invention, a solvent mixed with the charged particles 150 uses a non-polar organic solvent. Accordingly, the partition walls 130 may be formed of a non-polar polymer, an organic material, or an inorganic material having physical properties such as those of the solvent 155.

Sealing materials 140 are formed on the partition walls 130.

Referring to FIG. 3, an upper end of each of the partition walls 130 of the present invention has a width of about 10 um and matrix arrangement. The sealing materials 140 are coated on the upper end of each of the partition walls 130.

The sealing materials 140 act as an adhesive when the lower substrate 100 and the upper substrate 200 are coupled to each other. Also, the sealing materials 140 isolate the display solvent 160, filled in a unit pixel, not to be combined with each other. As a result, the sealing materials 140 seal a unit pixel region when the upper substrate 200 is coupled to the lower substrate 100.

The sealing materials 140 may be formed of a material having repulsion to the solvent 155 of the display solvent 160 in order for the display solvent 160 not to overflow to an adjacent unit pixel region. An inorganic material or an organic material having electrical isolation may be applied to the sealing materials 140.

The sealing materials 140 may be locally coated on the partition walls 130 by a micro-contact printing process, a gravure roll printing process or the like. The upper substrate 200 is adhered to the sealing materials 140, and then by hardening the sealing materials 140, the upper substrate 200 and the lower substrate 100 are coupled to each other. A process of irradiating light such as ultraviolet (UV) or a process of applying heat of a certain temperature to the sealing materials 140 may be selected as a process of hardening the sealing materials 140. Accordingly, in the embodiment, the sealing materials 140 may be thermosetting materials or photocurable materials.

The display solvent 160 charged in a unit pixel region is formed of a plurality of positive (+) or negative (−) charged particles 150 and the solvent 155 that enables moving of the charged particles 150.

The charged particles 150 may be colored in black or white when the electrophoretic display device has a monotype. The charged particles 150 may be selectively colored in red, blue, green, yellow, cyan, magenta, black, and white when the electrophoretic display device has a color type.

The solvent 155 may use halogenated solvents, saturated hydrocarbons, silicone oils, low molecular weight halogen-containing polymers, epoxides, vinyl ethers, vinyl ester, aromatic hydrocarbon, toluene, naphthalene, paraffinic liquids, or poly chlorotrifluoroethylene polymers.

Since the charged particles 150 are electrically charged, the solvent 155 may be non-polar in order not to perform an electric interaction with the charged particles 150.

The display solvent 160 including the charged particles 155 may be charged into a unit pixel region by a die coating process, a casting process, a bar coating process, a slit coating process, a dispense process, a squeezing process, a screen printing process, an inkjet printing process, or a photolithography process.

In this way, in the electrophoretic display device according to the first embodiment of the present invention, the display solvent 160 including the charged particles 150 and the solvent 155 is filled into a unit pixel region that is defined by each of the partition walls 130. Therefore, in the embodiment, since the display solvent 160 including electrophoretic particles is directly formed at the lower substrate 100, this is called an internalization type.

The upper substrate 200 includes a second substrate 205, and a common electrode 210. The upper substrate 200 may further include an interlayer 220.

The second substrate 205 needs be transparent for displaying an image. Therefore, the upper base substrate 205 is formed of a transparent glass or a transparent plastic material with flexibility. For example, the second substrate 205 may be a PET film.

The common electrode 210 is coated on the inner side of the second substrate 205. The common electrode 210 is disposed to face the pixel electrode 120, and forms an electric field in each unit pixel region. The charged particles 155 in the display solvent 160 move toward the upper substrate 200 or the lower substrate 100 by the electric field. The common electrode 210 is formed of a transparent conductive material such as ITO or indium zinc oxide (IZO).

The interlayer 220 may be further formed on the common electrode 210. The interlayer 220 prevents the charged particles 150 from being adhered to the common electrode 210 by an electric gravitation, and seals a unit pixel region together with the sealing materials 140.

The interlayer 220 may be formed of an inorganic material or an organic material having electrical isolation to have a thickness of about 0.1 um to about 40 um, under the common electrode 210.

To reinforce a sealing function for a unit pixel region, the interlayer 220 is formed of an organic material or an inorganic material (for example, SiNx or SiOx) that is hardened by UV and heat.

The interlayer 220 may be formed by a sputter process, a Chemical Vapor Deposition (CVD) process, a die coating process, a casting process, a bar coating process, a slit coating process, a dispense process, a squeezing process, a screen printing process, or an inkjet printing process.

When the interlayer 220 is formed of an organic material, a transparent nonconductive organic material or an organic material (which is capable of being coated with a polymer, an acrylic UV curable resin, or an organic self-assembled monolayer (SAM) layer) may be used as a material.

When the interlayer 220 is formed of an inorganic material, silicon nitride (for example, SiNx), amorphous silicon (a-Si), silicon oxide (for example, SiOx), aluminum oxide (for example, Al₂O₃), or a transparent nonconductive material may be used as a material.

Additionally, a protective film may be further adhered to the upper substrate 200, for protecting the first substrate 205 from an external environment.

When the electrophoretic display device has the monotype, the charged particles 150 may be colored in only black and white. When the electrophoretic display device has the color type, the charged particles 150 may be colored in red, blue, green, yellow, cyan, magenta, or yellow. In the color type, when charged particles of adjacent unit pixels including charged particles of different colors are mixed with each other, the quality of a color image is degraded.

In the electrophoretic display device according to the first embodiment of the present invention, the lower substrate 100 and the upper substrate 200 are coupled to each other with the interlayer 220 and sealing materials 140. Accordingly, charged particles included in adjacent unit pixels can be prevented from overflowing into other adjacent unit pixels and being mixed with other charged particles. Also, by sealing the display solvent 160 that is internalized in the lower substrate 100 with the interlayer 220 and the sealing materials 140, and thus, air and moisture can be prevented from penetrating into an active region.

Accordingly, the display quality and manufacturing efficiency of the electrophoretic display device can increase. Also, the stability and driving reliability of the charged particles 150 can be enhanced.

In the above description, it has been described that the lower substrate 100 and the upper substrate 200 are coupled to each other by forming the sealing materials 140 on the partition walls 130. However, this is one embodiment of the present invention. In another embodiment of the present invention, the lower substrate 100 and the upper substrate 200 may be coupled to each other by forming the sealing materials 140 on the upper substrate 200. For example, as illustrated in FIG. 3, the sealing materials 140 may be formed at the upper substrate 200 as in the plan view of each of the partition walls 130 having a matrix type. The sealing materials 140 are formed at the upper substrate 200, and then the sealing materials 140 may be accurately arranged with the partition walls 130 and couple the upper substrate 200 and the lower substrate 100.

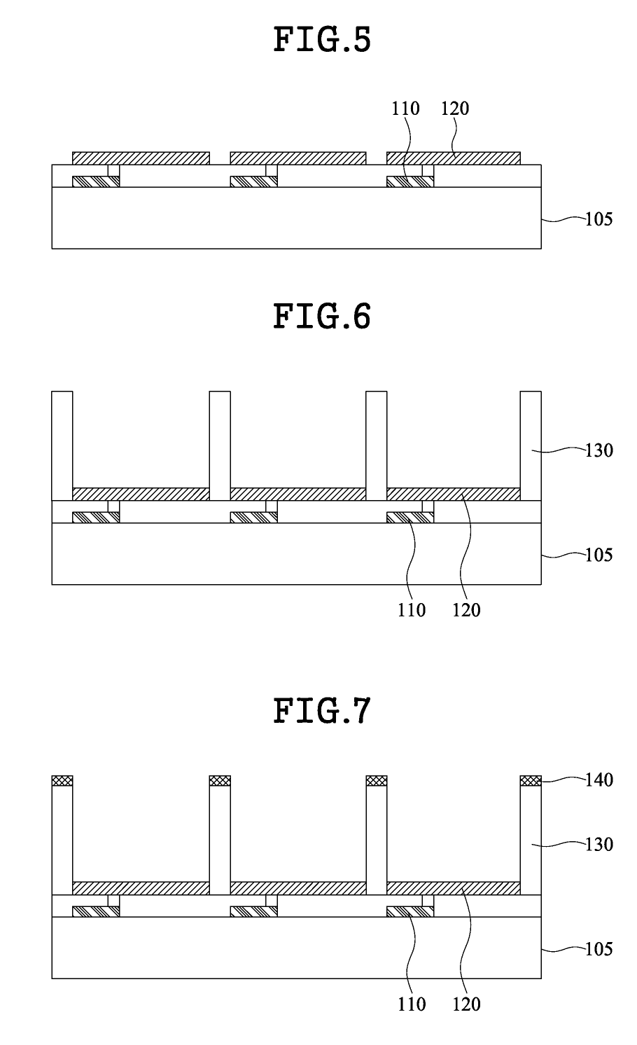

Hereinafter, a manufacturing method of an electrophoretic display device according to a first embodiment of the present invention will be described with reference to FIGS. 5 to 10. FIGS. 5 to 10 are views illustrating the essentials of a manufacturing method of an electrophoretic display device according to a first embodiment of the present invention.

Referring to FIG. 5, the thin film transistor 110 being a switching element that is formed in each unit pixel is formed on the first substrate 105. Although not shown in FIG. 5, before forming the thin film transistor 110 on the first substrate 105, an inorganic layer such as silicon nitride (SiNx) or silicon oxide (SiOx) may be first formed on the first substrate 105. The inorganic layer prevents moisture from penetrating into the active region. A process of forming a thin film transistor 110 on the inorganic is performed.

The process of forming the thin film transistor includes: a process of forming a gate line and a gate electrode; a process of forming a gate insulation layer on the gate line and the gate electrode; a process of forming a semiconductor layer on the gate insulation layer; a process of forming a data line and a data electrode on the semiconductor layer; a process of forming a passivation layer that covers the secmiconductor layer, the data line, and the data electrode; and a process of forming a contact hole, exposing the data electrode, on the passivation layer.

Subsequently, a conductive material such as Cu, Al, or ITO is coated, and then by performing a photolithography process and an etching process, the pixel electrode 120 is formed in each unit pixel. The pixel electrode 120 is connected to the data electrode through the contact hole.

The pixel electrode 120 may be formed by further stacking Ni and/or Au on the material such as Cu, Al, or ITO.

A transparent glass substrate, a plastic substrate with flexibility, or a metal substrate may be applied as the first substrate 105.

Referring to FIG. 6, a process of forming a plurality of partition walls on the first substrate 105 with the pixel electrode 120 formed therein is performed. The process of forming the partition walls includes: coating a photoresist on the first substrate 105 with a pixel electrode formed therein; and forming the partition walls by performing a photolithography process for the photoresist. Specifically, the photolithography process includes: forming the photoresist on the first substrate 105; aligning a mask on a photosensitive organic layer; exposing the photoresist with the mask; developing the exposed photoresist. The process of forming the partition walls may be a general photolithography process.

The photoresist may be a photosensitive organic layer or inorganic layer. Also, when the mask is seen from a plan view thereof, as illustrated in FIG. 3, the mask may be a mask that includes a lattice type opening portion so as to transmit light. That is, in the embodiment, when the photoresist is a negative photoresist that is hardened by exposure, the mask may include an opening portion corresponding to one of a plurality of partition walls.

As another process of forming a partition wall, a process of imprinting or mold printing the partition walls may be used.

The partition walls 130 surround pixel electrodes 120 and define a unit pixel region, respectively. Therefore, a space having a certain size is formed in each unit pixel by each of the partition walls 130. The display solvent 160 is filled into the space, namely, the unit pixel region.

Each of the partition walls 130 may be formed to have a height of about 10 um to about 100 um and a width of about 5 um to about 30 um. The height and thickness of each of the partition walls 130 may vary according to the size of a unit pixel. In the embodiment, however, each of the partition walls 130 has a height of about 40 um, a width of an upper end of each of the partition walls 130 is about 10 um, and the size of the unit pixel is about 100 um to about 150 um in width and height.

Referring to FIG. 7, the sealing materials 140 are formed by locally coating a sealing material on each of the partition walls 130 and then hardening the sealing material with UV. The sealing materials 140 are for attaching a lower substrate 100 and an upper substrate 200, and sealing the display solvent 160.

Herein, the sealing materials 140 may be formed of a material having repulsion to the solvent 155 of the display solvent 160 in order for the display solvent 160 not to overflow to an adjacent pixel.

The sealing materials 140 may be formed by locally coating a sealing material on each of the partition walls 130 in the micro-contact printing process or the gravure roll printing process and then hardening the sealing material with UV.

Herein, as another example of a process that coats the sealing material on each of the partition walls 130, a roll printing process, the die coating process, the casting process, the bar coating process, the slit coating process, the dispense process, the squeezing process, the screen printing process, the inkjet printing process, or the photolithography process may be used selectively.

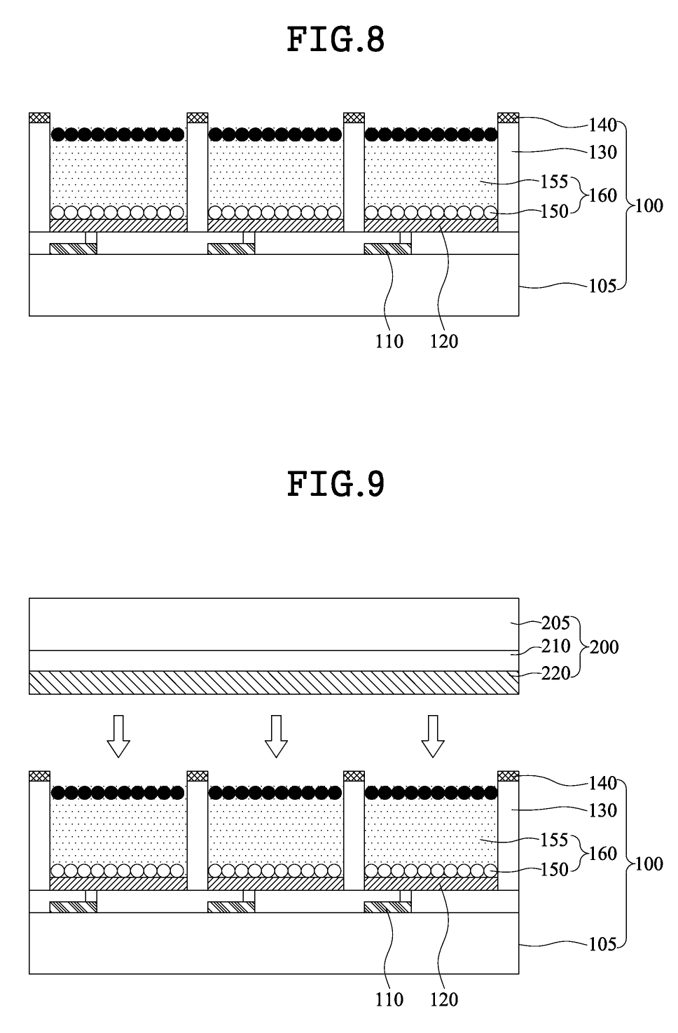

As illustrated in FIG. 8, the display solvent 160 is filled into the filling space that is defined by each of the partition walls 130.

The display solvent 160 may be charged into the filling space, defined by each of the partition walls 130, by the die coating process, the casting process, the bar coating process, the slit coating process, the dispense process, the squeezing process, the screen printing process, the inkjet printing process, or the photolithography process.

Herein, the display solvent 160 is configured with a plurality of positive (+) or negative (−) charged particles 150 and the solvent 155 including a binder.

The charged particles 150 may be selectively colored in red, blue, green, yellow, cyan, magenta, black, and white.

In FIG. 8, some of the charged particles 150 are colored in black, and the other of the charged particles 150 are colored in white.

The solvent 155 may use halogenated solvents, saturated hydrocarbons, silicone oils, low molecular weight halogen-containing polymers, epoxides, vinyl ethers, vinyl ester, aromatic hydrocarbon, toluene, naphthalene, paraffinic liquids, or poly chlorotrifluoroethylene polymers.

When the electrophoretic display device displays a full color image, the charged particles 150 are colored in color corresponding to color to be displayed by each pixel. In this case, a process of filling the display solvent 160 may be separately performed for each color that is colored on the charged particles 150.

In this way, the display solvent 160 including the charged particles 150 and the solvent 155 is filled into a pixel region that is defined by each of the partition walls 130, and thus, an electrophoretic layer is internalized in the lower substrate 100.

By forming the sealing materials 140 on the partition walls 130 with a material having repulsion to the solvent 155 of the display solvent 160, the electrophoretic display device can prevent the display solvent 160 from overflowing to another pixel. Also, the sealing materials 140 aid attaching of the lower substrate 100 and upper substrate 200, and thus enable smooth sealing of the display solvent 160.

Referring to FIG. 9, the upper substrate 200 is manufactured by a separate manufacturing process that differs from a manufacturing process of forming the lower substrate 100.

The common electrode 210 is formed of a transparent conductive material such as ITO or IZO, on the upper base substrate 205 that is formed of a transparent glass or a transparent plastic material with flexibility.

The common electrode 210 supplies a common voltage to each pixel region in correspondence with the pixel electrode 120, for driving of the charged particles 150.

The interlayer 220 is formed of an inorganic material or an organic material having electrical isolation, under the common electrode 210. In this case, the interlayer 220 is formed at a surface on which an image is displayed, and thus formed transparently.

The interlayer 220 is for sealing the display solvent 160 that is internalized in the lower substrate 100. Also, the interlayer 220 prevents the charged particles 150 from directly contacting the common electrode 210.

By using the interlayer 220 and the sealing materials 140 that are formed on the partition walls 130 of the lower substrate 100, the manufacturing method according to the first embodiment enables smooth attaching of the lower substrate 100 and upper substrate 200, and seals the display solvent 160 that is internalized in the lower substrate 100.

The interlayer 220 may be formed by the sputter process, the CVD process, the die coating process, the casting process, the bar coating process, the slit coating process, the dispense process, the squeezing process, the screen printing process, or the inkjet printing process.

The interlayer 220 is transparently formed of an organic material or an inorganic material that is hardened by UV and heat, and has a thickness of about 0.1 um to about 40 um, under the common electrode 210.

When the interlayer 220 is formed of an organic material, a transparent nonconductive organic material or an organic material (which is capable of being coated with a polymer, an acrylic UV curable resin, or an organic SAM layer) may be used as a material.

When the interlayer 220 is formed of an inorganic material, silicon nitride (for example, SiNx), amorphous silicon (a-Si), silicon oxide (for example, SiOx), aluminum oxide (for example, Al2O3), or a transparent nonconductive material may be used as a material.

When the electrophoretic display device displays a full color image, charged particles that are colored based on color displayed by a pixel may be charged into the pixel. Herein, when charged particles that are colored in red and charged into a red pixel overflow and penetrate into a blue pixel or green pixel adjacent thereto, a color image cannot be realized.

In the electrophoretic display device according to the first embodiment of the present invention, the lower substrate 100 and the upper substrate 200 are smoothly coupled to each other with the interlayer 220 and the sealing materials 140 that are formed on the partition walls 130 of the lower substrate 100. Also, by sealing the display solvent 160 that is internalized in the lower substrate 100, the penetration of air and moisture can be prevented.

Accordingly, the display quality and manufacturing efficiency of the electrophoretic display device can increase. Also, the stability and driving reliability of the charged particles 150 internalized in the lower substrate 100 can be enhanced.

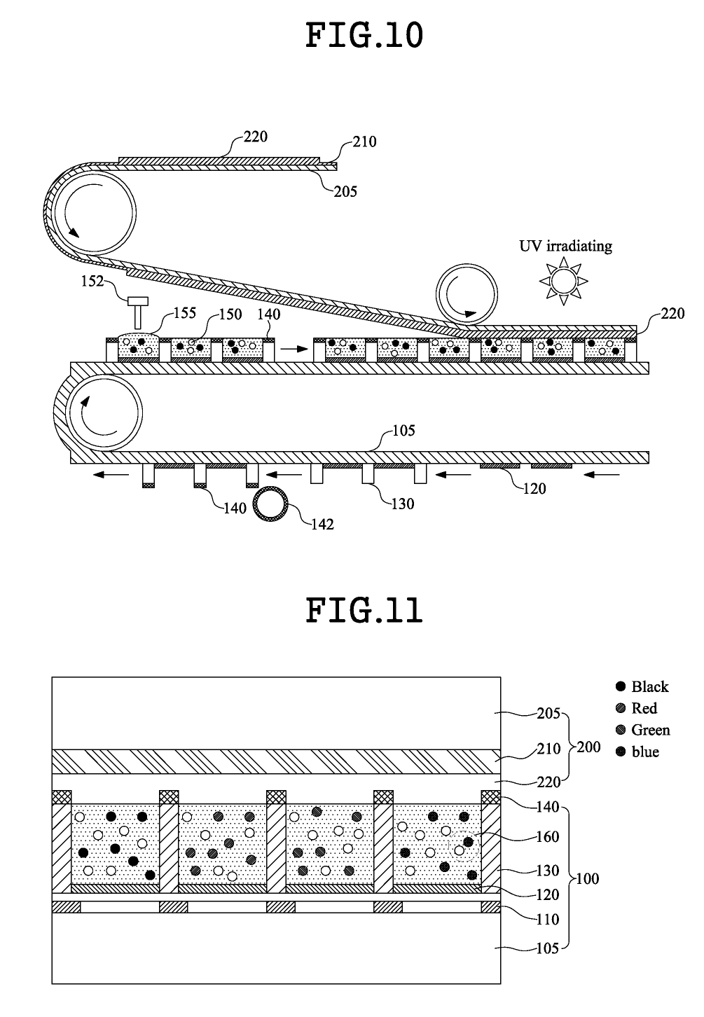

Referring to FIG. 10, the above-described manufacturing method of the electrophoretic display device according to the first embodiment of the present invention may successively perform a process of manufacturing the lower, a process of manufacturing the upper substrate 200, a process of sealing the display solvent 160 internalized in the lower substrate 100, and a process of attaching the lower substrate 100 and upper substrate 200, by using a roll-to-roll process.

The partition walls 130 are formed on the lower substrate 100, and thereafter the sealing material 142 is locally coated on each of the partition walls 130 by a roll printing process.

Subsequently, a dispense apparatus 152 fills the display solvent 160, including the charged particles 150 and solvent 155, into the filling space that is defined by each of the partition walls 130.

In manufacturing the lower substrate 100, the interlayer 220 is formed by coating a sealing material on the common electrode 210 of the upper substrate 200.

Afterward, the partition walls 130 with the sealing materials coated thereon and the interlayer 220 are arranged to face the upper substrate 200, and a roller couples the lower substrate 100 and the upper substrate 200 by applying a pressure.

At this point, by irradiating UV on the partition walls 130, the manufacturing method hardens the sealing material 142 coated on the partition walls 130, and thus forms the sealing materials 140. That is, the display solvent 160 internalized in the lower substrate 100 is sealed by using the sealing materials 140 formed on the partition walls 130 and the interlayer 220 formed on the upper substrate 200.

In this case, a process of attaching the lower substrate 100 and the upper substrate 200 may further use a pressurizing process of applying a certain pressure and an annealing process of applying a certain temperature.

By performing the above-described manufacturing process, the electrophoretic display device can be manufactured in which the display solvent 160 is internalized in the lower substrate 100.

In the above description, it has been described that the lower substrate 100 and the upper substrate 200 are coupled to each other by forming the sealing materials 140 on the partition walls 130. However, this is one embodiment of the present invention.

In another embodiment of the present invention, the lower substrate 100 and the upper substrate 200 may be coupled to each other by forming the sealing materials 140 on the upper substrate 200.

FIG. 11 is a view illustrating an electrophoretic display device according to a second embodiment of the present invention. In the description of the electrophoretic display device according to the second embodiment of the present invention, a description that is repetitive of the first embodiment is not provided.

Referring to FIG. 11, in the electrophoretic display device according to the second embodiment of the present invention, a plurality of charged particles 150 are selectively colored in red, blue, green, black, and white for displaying a full color image. That is, one unit pixel may be configured with four color pixels (for example, a mono pixel, a red pixel, a green pixel, and a blue pixel), thereby displaying a full color image.

In filling a display solvent 160 into a pixel region, sealing materials 140 prevents the display solvent 160 from overflowing and contaminating an upper end of each of the partition walls 130 or overflowing to an adjacent pixel. Also, the sealing materials 140 has a function of a sealing layer such that a lower substrate 100 and an upper substrate 200 are smoothly coupled to each other and the display solvent 160 charged into the lower substrate 100 is sealed smoothly.

The sealing materials 140 may be formed of materials repulsive to a solvent 155 of the display solvent 160 in order for the display solvent 160 not to overflow to an adjacent pixel. For example, the solvent of the display solvent of the present invention may use a non-polar organic solvent so as to facilitate moving of charged particles. In this case, the sealing materials 140 may be formed of electrically-charged hydrophilic materials repulsive to the non-polar organic solvent.

The sealing materials 140 may be repulsive to the solvent 155 of the display solvent 160, and moreover formed of materials having adhesive characteristic for adhesion of the upper substrate 200 and lower substrate 100.

Since the sealing materials 140 are repulsive to the display solvent 160, the sealing materials 140 can prevent the display solvent 160 from overflowing to on each of the partition walls 130. Herein, an inorganic material or an organic material having electrical isolation may be used as the material of the sealing materials 140.

As an example, a fluorine-based material or a material including a fluorine-based polymer is coated on the partition walls 130 by a plasma process, a contact printing process, a dipping process, or a gravure roll printing process. Subsequently, the sealing materials 140 may be formed by hardening the coated fluorine-based material or the coated material including the fluorine-based polymer.

The interlayer 220 is illustrated and has been described above as being formed at the upper substrate 200. However, this is one of several embodiments of the present invention.

As another embodiment of the present invention, the interlayer 220 may be formed just on the sealing materials 140 of the lower substrate 100, and then the lower substrate 100 and the upper substrate 200 may be coupled to each other.

Since the sealing materials 140 formed at the lower substrate 100 have a function of a sealing layer, the interlayer 220 of the upper substrate 200 may be applied optionally. When the upper substrate 200 does not include the interlayer 220, the thickness of the electrophoretic display device can decrease.

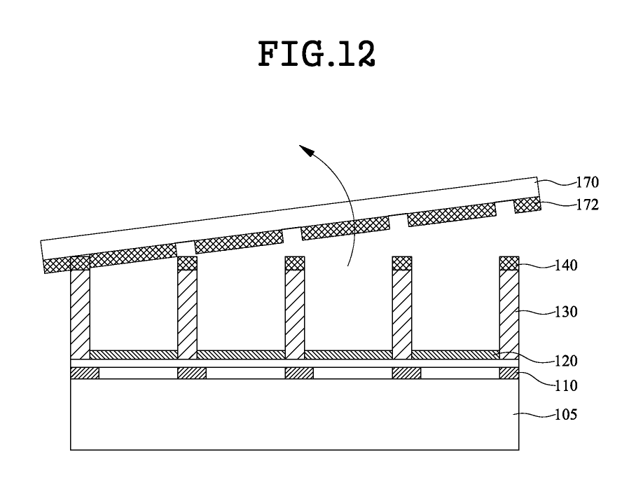

FIGS. 12 to 14 are views illustrating a manufacturing method of an electrophoretic display device according to a second embodiment of the present invention.

Referring to FIG. 12, in a manufacturing process, the sealing materials 140 may be formed of materials repulsive to the solvent 155 of the display solvent 160 in order for the display solvent 160 not to overflow to an adjacent pixel, on the partition walls 130.

The sealing materials 140 may be repulsive to the solvent 155 of the display solvent 160, and moreover formed of a sealant for attaching of the lower substrate 100 and upper substrate 200 and sealing of the display solvent 160.

Specifically, an inorganic material or an organic material having electrical isolation is coated on the partition walls 130. Subsequently, the sealing materials 140 are formed by hardening the coated organic material or inorganic material.

As an example, a film 170, on which a fluorine-based material or a sealing material 172 including a fluorine-based polymer is coated, is aligned over the partition walls 130. Subsequently, the sealing material 172 is locally coated on the partition walls 130 by the contact printing process. Afterward, the sealing materials 140 may be formed by hardening the coated sealing material 172.

The fluorine-based material or the sealing material 172 including the fluorine-based polymer may be coated on the partition walls 130 by the plasma process, the dipping process, or the gravure roll printing process, in addition to the contact printing process. Subsequently, the sealing materials 140 may be formed by hardening the coated sealing material 172.

In filling a display solvent 160 into a pixel region, the sealing materials 140 prevent the display solvent 160 from overflowing and contaminating an upper end of each of the partition walls 130 or overflowing to an adjacent pixel. Also, the sealing materials 140 enables smooth attaching of the lower substrate 100 and upper substrate 200 and smooth sealing of the display solvent 160.

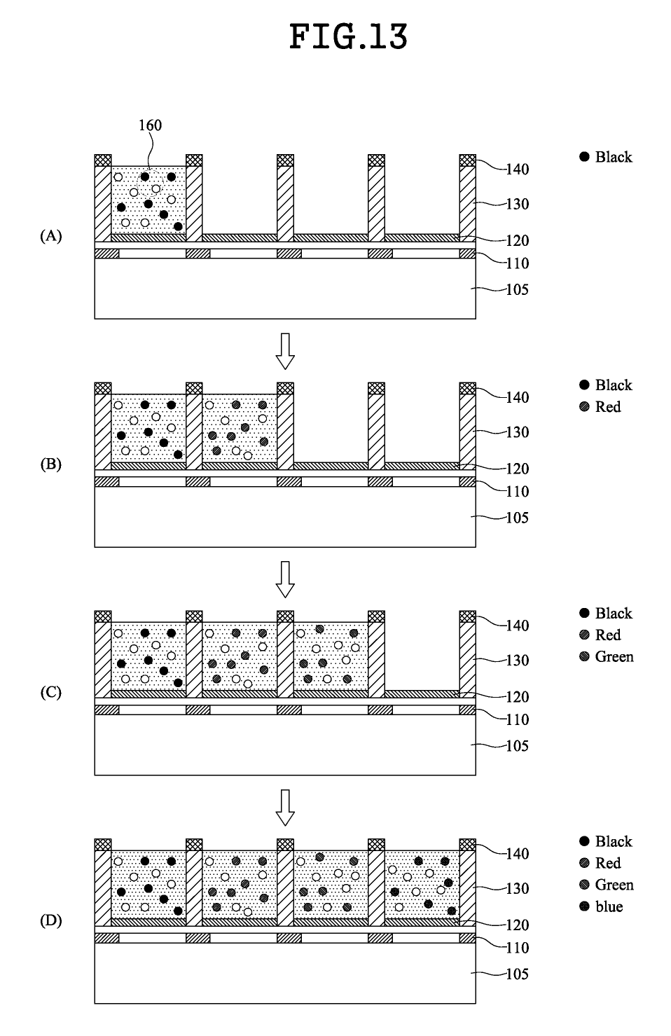

Referring to FIG. 13, the display solvent 160 is filled into each unit pixel region defined by each of the partition walls 130.

As an example, the display solvent 160 may be charged into each unit pixel region by a dispense process using the dispense apparatus 152.

As another example, the display solvent 160 may be charged into a unit pixel region by the die coating process, the casting process, the bar coating process, the slit coating process, the squeezing process, the screen printing process, the inkjet printing process, or the photolithography process, in addition to the dispense process.

When the electrophoretic display device displays a full color image, the charged particles 150 are colored in color corresponding to color to be displayed by each pixel. In this case, a process of filling the display solvent 160 may be sequentially performed for respective colors that are colored on the charged particles 150.

In this case, a micro needle injecting apparatus may charge the display solvent 160 into each color pixel. Furthermore, a screen printing process using a mask may charge the display solvent 160 into each color pixel.

As an example, as illustrated in a portion (A) of FIG. 13, a display solvent including a plurality of charged particles colored in black and white is filled into a plurality of corresponding sub-pixels.

Subsequently, as illustrated in a portion (B) of FIG. 13, a display solvent including a plurality of charged particles colored in red is filled into a plurality of corresponding sub-pixels.

Afterward, as illustrated in a portion (C) of FIG. 13, a display solvent including a plurality of charged particles colored in green is filled into a plurality of corresponding sub-pixels.

Thereafter, as illustrated in a portion (D) of FIG. 13, a display solvent including a plurality of charged particles colored in blue is filled into a plurality of corresponding sub-pixels. In a color electrophoretic display device, four sub-pixels with red, green, blue, black, and white particles injected thereinto configure one unit pixel.

When the electrophoretic display device has the monotype, the charged particles 150 charged into total unit pixels are colored in black and white, and thus, a display solvent can be simultaneously charged into the total unit pixels.

In this way, the display solvent 160 is filled into a unit pixel region defined by each of the partition walls 130, and thus, an electrophoretic layer may be internalized in the lower substrate 100.

In this case, since the sealing materials 140 are formed of materials repulsive to the display solvent 160 on each of the partition walls 130, the sealing materials 140 can prevent the display solvent 160 from overflowing to adjacent pixels and enables the display solvent 160 to be accurately charged into the filling space.

Although not shown, filling of the display solvent 160 is completed, and then, by removing a portion of the solvent 155 in a spin-coating process, the uniformity of the display solvent 160 can be secured.

At this point, a portion of the solvent 155 may be removed such that an amount of the charged display solvent 160 reaches about 80% of a filling space in a pixel region.

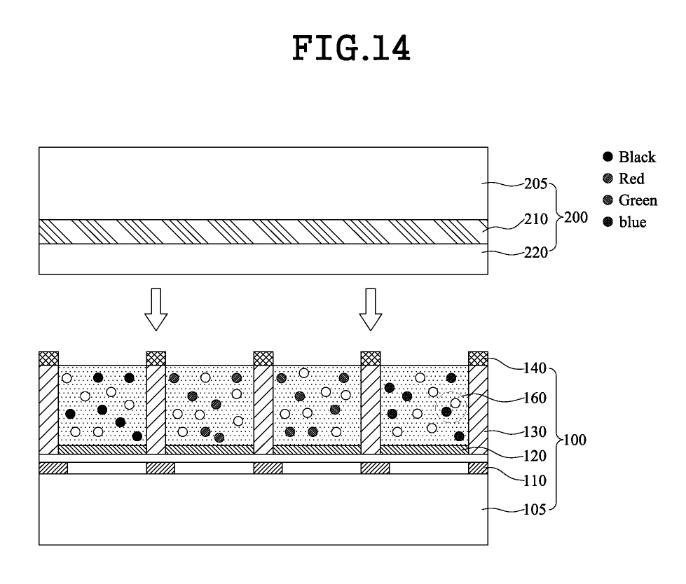

Referring to FIG. 14, the lower substrate 100 and the upper substrate 200 are aligned, and then, by applying a certain pressure in a roll-to-roll process, the lower substrate 100 and the upper substrate 200 are coupled to each other. In this case, a process of attaching the lower substrate 100 and the upper substrate 200 may further use a pressurizing process of applying a certain pressure and a heating process of applying a certain temperature.

The interlayer 220 and the sealing materials 140 formed on the partition walls 130 of the lower substrate 100 enable smooth attaching of the lower substrate 100 and upper substrate 200, and allow the display solvent 160 internalized in the lower substrate 100 to be sealed.

Moreover, the interlayer 220 allows the display solvent 160 internalized in the lower substrate 100 to be sealed, thus preventing the penetration of air and moisture into a unit pixel region.

In the electrophoretic display device manufactured according to the embodiments of the present invention, the charged particles 150 of the display solvent 160 charged into each pixel region move inside the solvent 155 according to an electric field that is generated by the data voltage applied to each of the pixel electrodes 120 and the common voltage applied to the common electrode 210, thereby displaying a mono image and a color image.

According to the embodiments of the present invention, the display quality and manufacturing efficiency of the electrophoretic display apparatus can increase. Also, the stability and driving reliability of the charged particles internalized in the lower substrate 100 can be enhanced.

In the above description, the interlayer 220 is illustrated and has been described above as being formed at the upper substrate 200. However, this is one of several embodiments of the present invention. As another embodiment of the present invention, the interlayer 220 may be formed just on the sealing materials 140 of the lower substrate 100, and then the lower substrate 100 and the upper substrate 200 may be coupled to each other.

The manufacturing method of the electrophoretic display device, according to the above-described embodiments of the present invention, may apply a manufacturing infra that is used in the existing method manufacturing LCD devices.

According to embodiments, the present invention can provide the electrophoretic display device with enhanced display quality and the manufacturing method thereof.

According to embodiments, the present invention can provide can enhance the manufacturing efficiency of the electrophoretic display device.

According to embodiments, the present invention can provide the electrophoretic display device and the manufacturing method thereof that can enhance the stability and driving reliability of the charged particles that are internalized in the lower substrate.

According to embodiments, the present invention can provide the electrophoretic display device which can realize a high-quality image in various colors, and the manufacturing method thereof.

According to embodiments, the manufacturing method of the electrophoretic display device can enhance the productivity of the electrophoretic display device.

According to embodiments, the present invention can provide the manufacturing method of the electrophoretic display device that can internalize the display solvent in the lower substrate.

According to embodiments, the manufacturing method of the electrophoretic display device can prevent the display solvent from overflowing to adjacent pixels when internalizing the display solvent in the array substrate.

In addition to the aforesaid features and effects of the present invention, other features and effects of the present invention can be newly construed from the embodiments of the present invention.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. An electrophoretic display device comprising:
a plurality of partition walls formed at a first substrate, and defining a plurality of unit pixel regions;
sealing materials formed on the partition wall;
a display solvent comprising a plurality of charged particles and a solvent, and filled into the unit pixel regions; and
a second substrate adhered to the sealing materials to seal the unit pixel regions.

2. The electrophoretic display device of claim 1, wherein the sealing materials are formed of a material having repulsion to the solvent of the display solvent.

3. The electrophoretic display device of claim 1, wherein the sealing materials are formed of fluorine-based materials or materials comprising a fluorine-based polymer.

4. The electrophoretic display device of claim 1, wherein the second substrate further comprises a sealing layer adhered to the sealing materials to seal the unit pixel regions.

5. The electrophoretic display device of claim 4, wherein the sealing materials and the sealing layer are formed of a nonconductive organic or inorganic material which cannot chemically react with the charged particles.

6. The electrophoretic display device of claim 4, wherein the sealing layer is transparently formed to have a thickness of about 0.1 um to about 40 um.

7. The electrophoretic display device of claim 1, wherein the charged particles have one color which is selected from red, blue, green, yellow, cyan, magenta, black, and white.

8. The electrophoretic display device of claim 4, wherein the sealing layer and the partition walls are formed of a non-polar organic material.

9. The electrophoretic display device of claim 1, wherein the solvent comprises halogenated solvents, saturated hydrocarbons, silicone oils, low molecular weight halogen-containing polymers, epoxides, vinyl ethers, vinyl ester, aromatic hydrocarbon, toluene, naphthalene, paraffinic liquids, or poly chlorotrifluoroethylene polymers.

10. The electrophoretic display device of claim 1, wherein,
the first substrate further comprises a plurality of unit pixel electrodes formed in each of the unit pixel regions, and
the second substrate further comprises a common electrode facing the unit pixel electrode to form an electric field.

11. A manufacturing method of an electrophoretic display device, the manufacturing method comprising:
forming a plurality of partition walls which define a plurality of unit pixel regions, at a first substrate;
forming sealing materials on the partition walls;
filling a display solvent into the unit pixel regions, the display solvent comprising a plurality of charged particles and a solvent; and
attaching the first substrate to a second substrate corresponding to the first substrate.

12. The manufacturing method of claim 11, wherein the forming of sealing materials on the partition walls comprises:
coating the sealing materials on a roller; and
transferring the sealing materials, coated on the roller, to an upper end of the partition walls.

13. The manufacturing method of claim 11, wherein the forming of sealing materials on the partition walls comprises:
coating the sealing materials on a transfer substrate; and
transferring the sealing materials, coated on the transfer substrate, to an upper end of the partition walls.

14. The manufacturing method of claim 11, wherein the forming of a plurality of partition walls at a first substrate comprises:
forming a photosensitive organic layer on the first substrate;
aligning a mask on the photosensitive organic layer;
exposing the photosensitive organic layer with the mask; and
developing the exposed photosensitive organic layer.

15. The manufacturing method of claim 11, wherein the attaching of the first substrate comprises:
adhering the second substrate to the sealing materials on the partition walls; and
hardening the sealing materials.

16. The manufacturing method of claim 11, further comprising:
forming a transparent conductive layer on the second substrate; and
forming an interlayer on the conductive layer.

17. The manufacturing method of claim 16, further comprising sealing the display solvent filled into the unit pixel regions by attaching the sealing materials and the interlayer.

18. The manufacturing method of claim 11, wherein the sealing materials are coated on the partition walls by a plasma process, a contact printing process, a dipping process, a gravure roll printing process, a die coating process, a casting process, a bar coating process, a slit coating process, a dispense process, a squeezing process, a screen printing process, an inkjet printing process, or a photolithography process.
